(19) United States
(12) Patent Application Publication
(10) Pub. No.: US 2011/0108088 A1
(43) Pub. Date: May 12, 2011

(54) PHOTOVOLTAIC STRUCTURE AND METHOD OF USE

(75) Inventors: James R. Young, Dearborn, MI (US); Thomas J. Denniston, Temperence, MI (US)

(73) Assignee: Xunlight Corporation, Toledo, OH (US)

(21) Appl. No.: 12/942,404

(22) Filed: Nov. 9, 2010

Related U.S. Application Data
(60) Provisional application No. 61/259,543, filed on Nov. 9, 2009.
(60) Provisional application No. 61/259,941, filed on Nov. 10, 2009.

(51) Int. Cl. H01L 31/048; B23P 11/00

(52) U.S. Cl. 136/245; 136/251; 29/428

(57) ABSTRACT

A photovoltaic structure is provided. The photovoltaic structure includes a photovoltaic module having a top surface, a bottom surface, and a perimeter. The photovoltaic structure also includes a plurality of flexible tabs attached to the photovoltaic module bottom surface, wherein the plurality of flexible tabs extend beyond the perimeter of the photovoltaic module. A method for mounting a photovoltaic module is also provided.

### RELATED APPLICATIONS

This application is claiming the benefit, under 35 U.S.C. 119(e), of the provisional application which was granted Ser. No. 61/259,543 filed on Nov. 9, 2009 and the provisional application which was granted Ser. No. 61/259,941 filed on Nov. 10, 2009 under 35 U.S.C. 111(b). These provisional applications are hereby incorporated by reference.

### BACKGROUND OF THE INVENTION

A photovoltaic (PV) module may be constructed by electrically connecting one or more solar cells in series and encapsulating the cells between protective layers. Generally, the PV module has a top (facing the sun) protective layer and a bottom protective layer. For flexible PV modules, the top and bottom layers may be thin sheets of a polymeric material. The bottom layer polymeric sheet is usually referred to as a back sheet.

Typically, flexible PV modules are installed by directly attaching the module back sheet to a surface with an adhesive. Traditional surfaces for attaching flexible PV modules to are commercial and residential rooftops. However, the prior art methods and systems for attaching flexible PV modules to these surfaces make module removal difficult or results in damage to the module during removal. Additionally, these prior art methods and systems are limited in their applicability to non-traditional surfaces such as earthen surfaces.

Therefore, a need exists for a PV structure which allows PV modules to be easily attached to and removed from most surfaces.

### BRIEF SUMMARY OF THE INVENTION

The present invention is directed to photovoltaic structures. A method for mounting a photovoltaic module is also provided.

The photovoltaic structure comprises a photovoltaic module. The photovoltaic module has a top surface, a bottom surface, and a perimeter. The photovoltaic structure also comprises a plurality of flexible tabs attached to the photovoltaic module. Each of the plurality of flexible tabs extends beyond the perimeter of the photovoltaic module. The plurality of flexible tabs are for mounting the photovoltaic module to a surface structure.

In another configuration, the photovoltaic structure comprises a photovoltaic module. The photovoltaic module has a top surface, a bottom surface, and edge portions. The photovoltaic structure further comprises a plurality of flexible tabs attached to the photovoltaic module. At least two flexible tabs are attached to bottom surface edge portions of the photovoltaic module. Additionally, the photovoltaic structure comprises a surface structure attached to the plurality of flexible tabs so that a space is provided between the surface structure and the bottom surface of the photovoltaic module.

The method for mounting a photovoltaic module comprises providing a photovoltaic module. The photovoltaic module is attached to a plurality of flexible tabs and is positioned above a surface structure. The plurality of flexible tabs are attached to the surface structure. Additionally, the method comprises removing the photovoltaic module from above the surface structure.

### BRIEF DESCRIPTION OF THE DRAWINGS

FIG. 1 is a top perspective view of a photovoltaic structure of the present invention;

FIG. 2 is a cross-sectional view of the photovoltaic structure taken along the line 2-2 of FIG. 1;

FIG. 3 is a top perspective view of a photovoltaic structure of the present invention;

FIG. 4 is a cross-sectional view of the photovoltaic structure taken along the line 4-4 of FIG. 3;

FIG. 5 is a top perspective view of a photovoltaic structure of the present invention;

FIG. 6 is a perspective view of a photovoltaic structure of the present invention;

FIG. 7 is a perspective view of a photovoltaic structure of the present invention;

FIG. 8 is a perspective view of a photovoltaic structure of the present invention;

FIG. 9 is a perspective view of a photovoltaic structure of the present invention; and

FIG. 10 is a perspective view of a photovoltaic structure of the present invention.

### DETAILED DESCRIPTION OF THE INVENTION

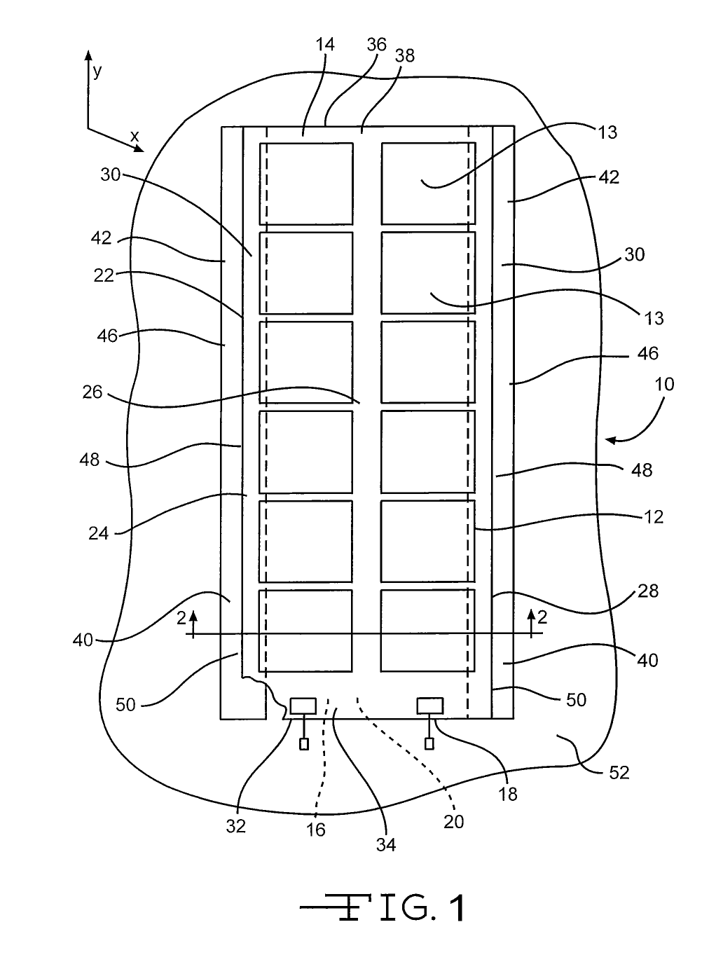

It is to be understood that the invention may assume various alternative orientations and step sequences, except where expressly stated to the contrary. It should also be appreciated that the methods described and structures illustrated in FIGS. 1-10 and described in the following specification are simply exemplary embodiments of the inventive concepts defined in the appended claims. For example, although the present invention will be described in connection with PV modules having at least one PV cell having an amorphous silicon (a-Si) single junction (SJ) or a triple junction of a-Si the present invention is not so limited. As such, the present invention may include PV cells having at least one single junction (SJ) of cadmium telluride (CdTe), amorphous silicon germanium (a-SiGe), amorphous silicon (a-Si), crystalline silicon (c-Si), microcrystalline silicon (mc-Si), nanocrystalline silicon (nc-Si), CIS, CIGS, or CIGSe.

FIGS. 1-10 depict embodiments of the PV structure 10 of the present invention.

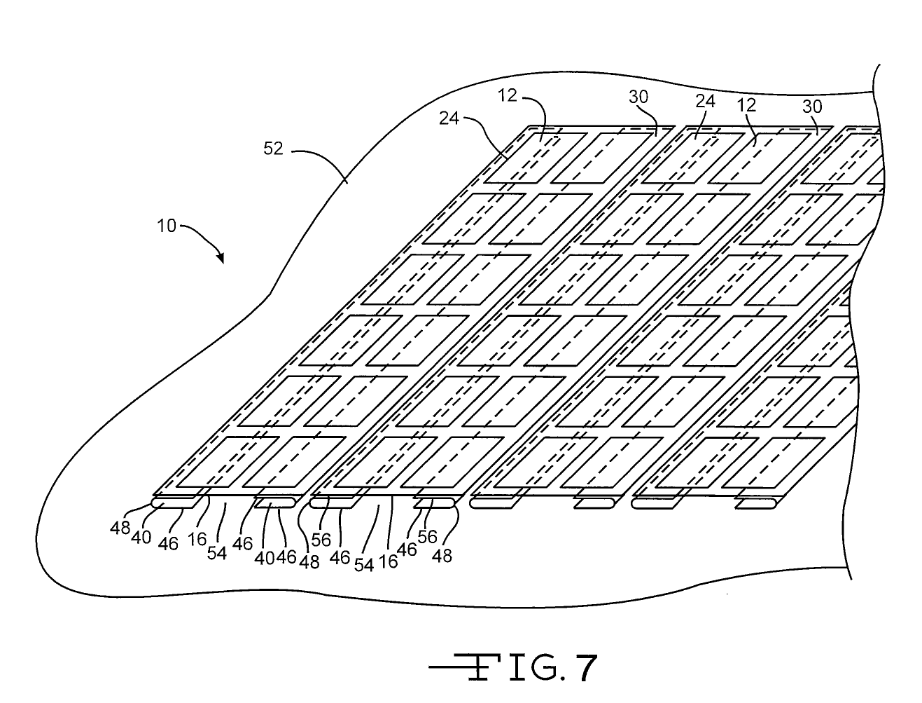

As shown in FIGS. 1, 3 and 5, the PV structure 10 comprises at least one PV module 12. However, as shown in FIGS. 6-10, the PV structure 10 may comprise a plurality of PV modules 12. As would be appreciated by those skilled in the art, each PV module 12 includes a plurality of electrically connected solar cells 13. In an embodiment, the at least one PV module 12 is flexible. For example, the at least one PV module 12 may be an XR-12 or an XR-36 sold by the Xunlight Corporation. However, in other embodiments, the PV module 12 may be rigid or semi-rigid.

As best seen in FIGS. 1-4, the at least one PV module 12 includes a transparent top (facing the sun) surface 14, a bottom surface 16, and a perimeter 18.

The transparent top surface 14 prevents corrosion of the solar cells 13 while allowing for high light transmission. Preferably, the transparent top surface 14 is composed of ETFE, EVA, or a combination thereof.

The bottom surface 16 includes a back sheet 20. The back sheet 20 provides moisture protection, UV stability, and weatherability. For describing the present invention, the back sheet 20 will be referred to as the outermost layer of the PV module which is located opposite the top surface 14. However, the back sheet 20 may be a multi-layer laminate. An example of a suitable back sheet material is a fluoropolymer such as TPE, FPE, KPE and TPT. In an embodiment, the back sheet 20 is a multi-layer laminate comprising polyethylene polyester. Examples of suitable polyethylene polyester multi-layer laminates comprise EPE and EP.

Both the PV module top surface 14 and bottom surface 16 include a first Y edge 22, a first Y edge portion 24, a center portion 26, a second Y edge 28, and a second Y edge portion 30. The PV module 12 also includes a first X edge 32, a first X edge portion 34, a second X edge 36, and a second X edge portion 38. The first Y edge 22, second Y edge 28, first X edge 32, and second X edge 36 form the PV module perimeter 18.

The PV structure 10 further comprises a plurality of flexible tabs 40. Each flexible tab 40 may be composed of a reinforced flexible membrane material. For example, the reinforced flexible membrane material may be comprised of one or more of high density polyethylene (HDPE), EPDM, TPO, Hypalon, or PIB. In another embodiment, each flexible tab 40 is composed of PVC. In a further embodiment, the plurality of flexible tabs 40 are composed of an elastomeric material. Preferably, the PV module bottom surface 16 is composed of a different material than the plurality of flexible tabs 40.

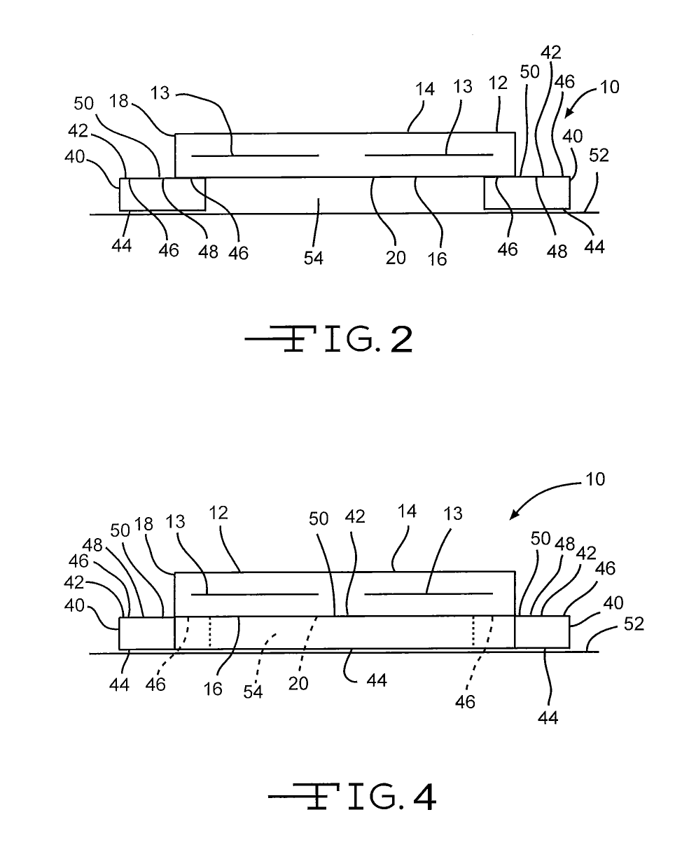

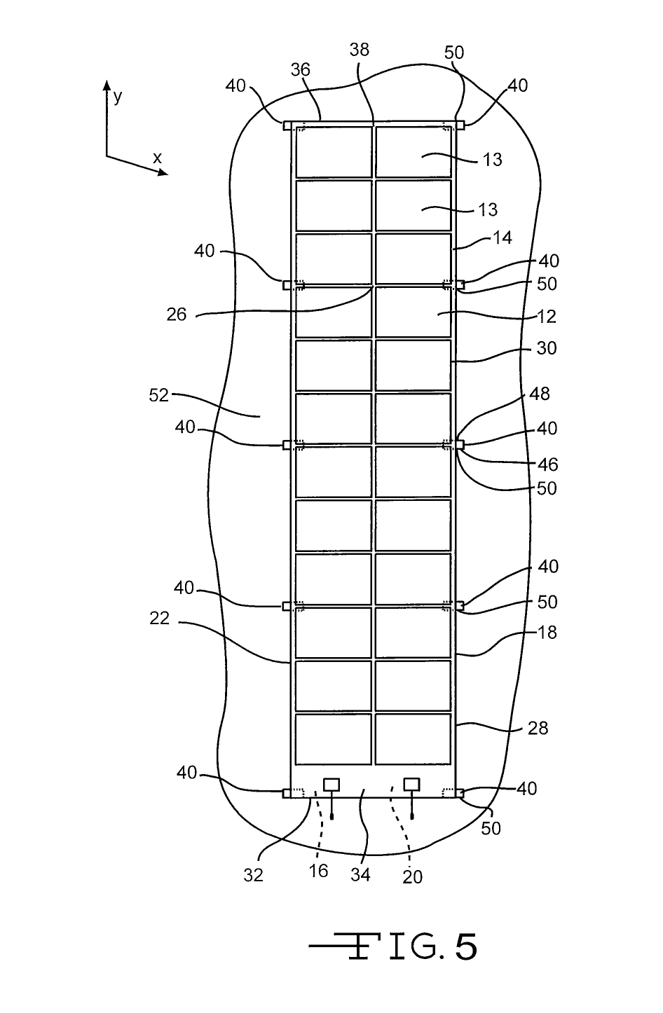

As shown best in FIGS. 2 and 4, each flexible tab 40 has a first surface 42 and a second surface 44. Each flexible tab 40 also has a pair of side portions 46 separated by a center portion 48. The tab first surface 42 is attached to the PV module bottom surface 16. Preferably, a side portion 46 of the tab first surface 42 is attached to a PV module 12. The plurality of flexible tabs 40 are attached to the PV module bottom surface 16 with an adhesive or mechnically. Preferably, a butyl, acrylic, polyurethane, or a silicon adhesive is utilized for attaching the plurality of flexible tabs 40 to the PV module bottom surface 16. Each flexible tab 40 may be attached to the PV module 12 after the PV module 12 is formed. As such, the plurality of flexible tabs 40 and the PV module 12 may not form a unitary body.

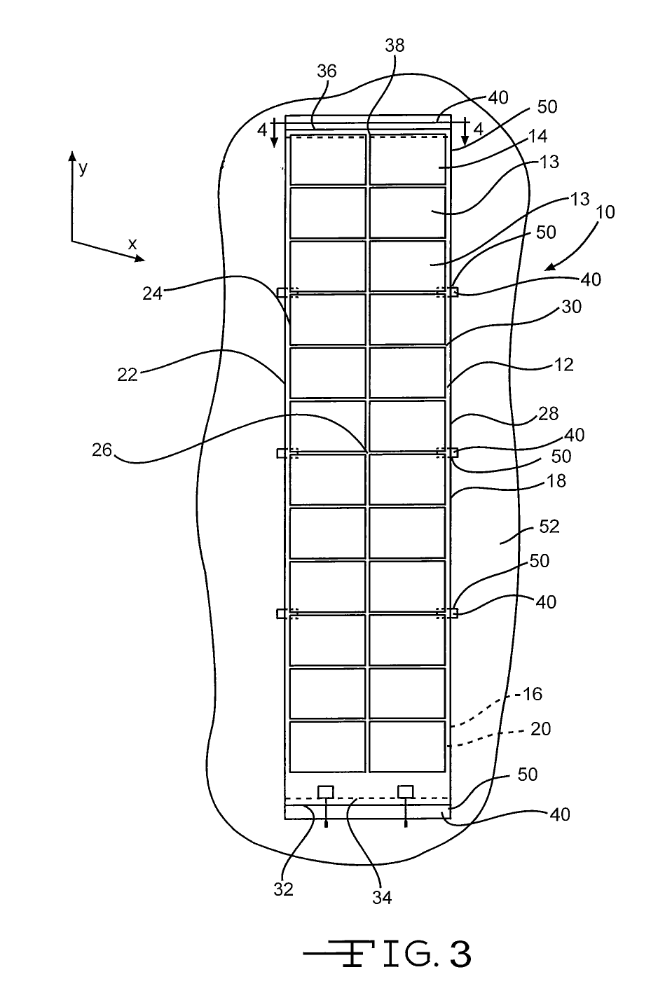

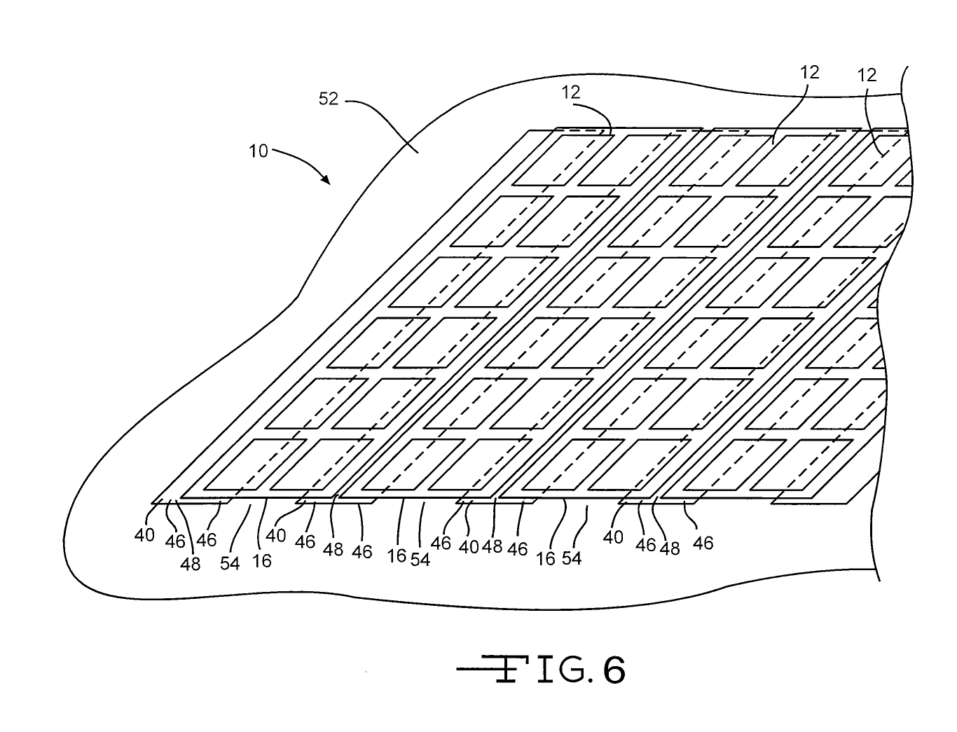

As described above, each flexible tab 40 is attached to the PV module bottom surface 16. As shown in FIG. 1, in an embodiment, a flexible tab 40 is attached to and extends along both bottom surface Y edge portions 24, 30. As shown in FIG. 3, in an embodiment, a flexible tab 40 is attached to and extends along an entire bottom surface X edge portion 34, 38. Additionally, a plurality of flexible tabs 40 are also attached to the bottom surface Y edge portions 24, 30. As shown in FIG. 5, in an embodiment, a plurality of flexible tabs 40 are attached to the bottom surface Y edge portions 24, 30 and the bottom surface X edge portions 34, 38. In this embodiment, none of the flexible tabs 40 extend the entire length of an edge portion 24, 30, 34, 38.

Each tab 40 is a separate body from an adjacent tab 40. In this manner, the use of tab material and PV structure costs are minimized. As depicted in FIG. 1, in an embodiment, the plurality of flexible tabs 40 extend beyond only two opposite edges 22, 28 of the PV module perimeter 18. As depicted in FIG. 3, in another embodiment, a flexible tab 40 extends beyond both the X and Y edges 22, 28, 32, 36 of the PV module perimeter 18. As depicted in FIG. 5, in an embodiment, each flexible tab 40 extends beyond only the Y edges 22, 28 of the PV module perimeter 18. Thus, in an embodiment, a portion 50 of each of the plurality of flexible tabs 40 extends beyond an edge 22, 28, 32, 36 the PV module perimeter 18. Additionally, in these embodiments, each tab 40 is separated from a tab 40 attached to an opposite PV module edge portion 24, 30, 34, 38 by the PV module bottom surface center portion 26.

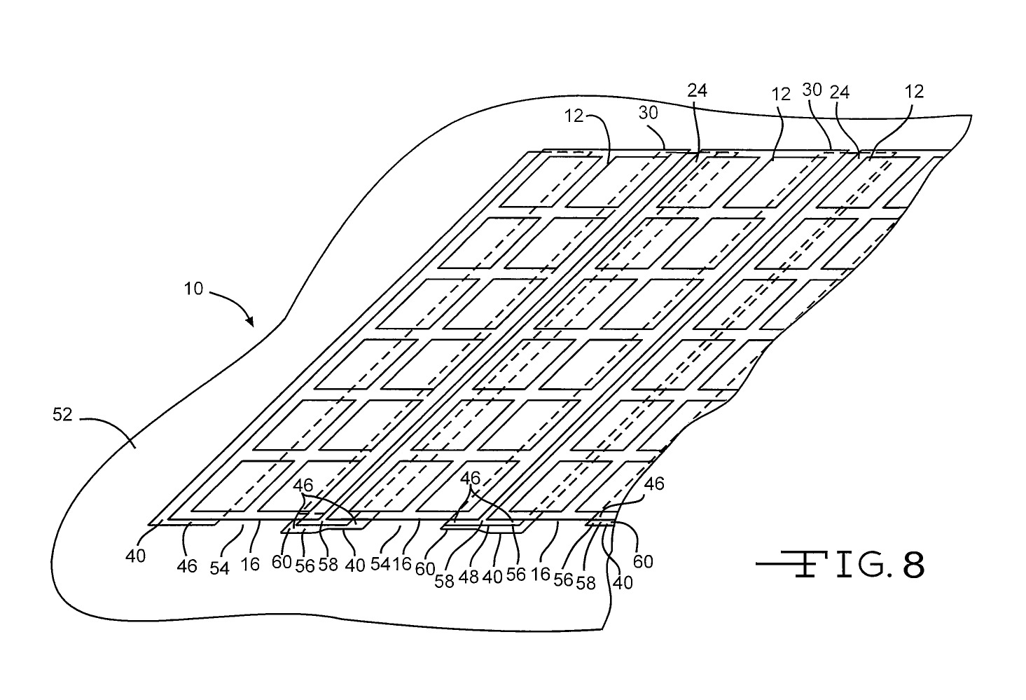

As stated above and as shown in FIGS. 6-10, in embodiments, the PV structure 10 may comprise a plurality of PV modules 12. In FIGS. 6 and 8-10, a plurality of flexible tabs 40 are attached to a PV module 12 on their side portions 46. Preferably, the plurality of flexible tabs first surface side portions 46 have an adhesive disposed for attachment to the PV modules 12. As depicted in FIGS. 6 and 8-10, each tab first surface side portion 46 is attached by an adhesive or mechanically to two PV modules 12. Thus, two PV modules 12 can be physically connected together. Those skilled in the art would appreciate that a tab 40 can be attached to more than two PV modules 12. However, as shown in FIG. 7, the PV modules 12 are not physically connected to each other. Additionally, as shown in FIGS. 6-10, the tab first surface center portion 48 is not attached to a PV module 12.

The PV structure 10 may also comprise a surface structure 52. Each tab 40 may be attached to the surface structure 52. After attaching the tabs 40 to the surface structure 52, a space 54 is provided between the bottom surface 16 of a PV module 12 and the surface structure 52. The space 54 may provide enhanced cooling of a PV module 12 by allowing for air flow across the PV module bottom surface 16. Surface structures 52 especially well-suited for use in the present invention are roof tops, walls, landfill caps, geomembranes, earthen surfaces, or surface structures with an even or uneven topology.

In the embodiments shown in FIGS. 1-8, the surface structure 52 has the same composition as the tab material. Utilizing a tab material that has the same composition as the surface structure 52 or installation surface allows PV modules 12 to be attached to the surface structure 52 by welding without the use of an adhesive. Additionally, if an adhesive is required, the present invention allows the adhesive to be used without the need to employ a primer. Preferably, where a portion 50 of the flexible tabs 40 extends beyond the edge 22, 28, 32, 36 the PV module perimeter 18, the portion 50 is attached to the surface structure 52.

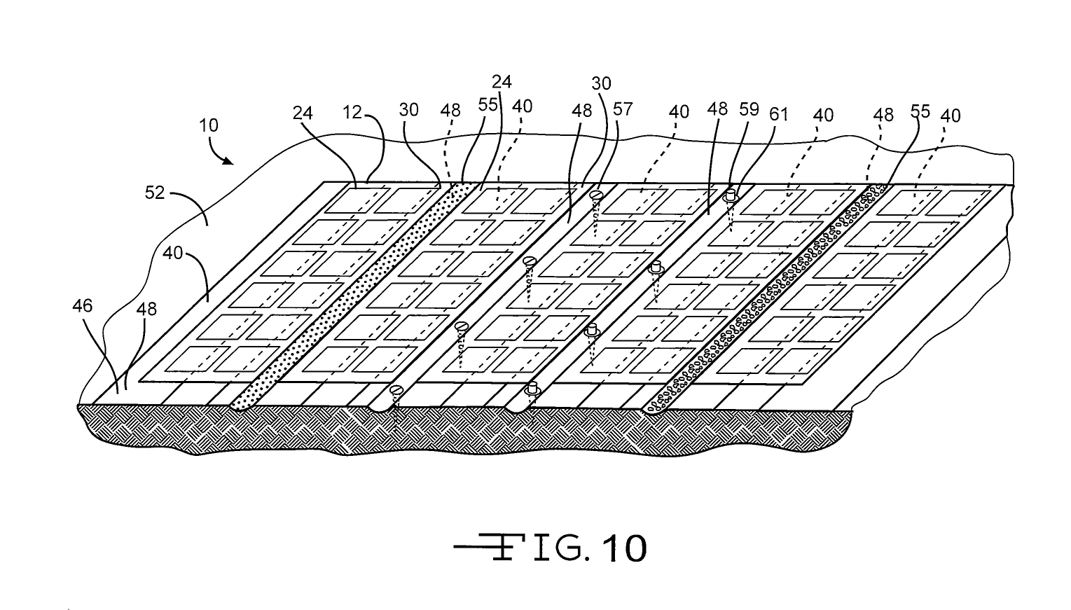

However, in the embodiments shown in FIGS. 9 and 10, the surface structure 52 may be earthen. In these embodiments, the surface structure 52 may be graded to provide a slope. Additionally, in these embodiments, the composition of the surface structure 52 is different than the composition of the tab material.

As stated above, the plurality of flexible tabs 40 are attached to the surface structure 52. In the embodiments shown in FIGS. 1-8, the plurality of flexible tabs 40 may be attached to the surface structure 52 via an adhesive, mechanically, or via welding. As shown In the embodiment of FIG. 9, the plurality of flexible tabs 40 may be attached to the surface structure 52 via ballasting. In the embodiment shown in FIG. 10, the plurality of tabs 40 may be attached to the surface structure 52 via ballasting, mechanically, or with combinations thereof. Preferably, when the surface structure 52 is earthen and ballasting is utilized to attach the plurality of flexible tabs 40 to the surface structure 52, at least the center portion 48 of the flexible tabs 40 is covered with ballast material 55. Additionally, as depicted in FIG. 10, when the surface structure 52 is earthen and the plurality of flexible tabs 40 are mechanically attached to the surface structure 52, ground anchors 57, stakes 59, or a combination thereof may be utilized for attachment. Preferably, when ground anchors 57 or stakes 59 are utilized for attachment, grommets 61 may be provided in the flexible tab center portion 48. The ground anchors 57 or stakes 59 extend through the grommets 61 and into the earthen surface structure 52.

FIG. 7 depicts another embodiment of the present invention. As shown, a plurality of flexible tabs 40 are attached to the PV module bottom surface 16 and to the surface structure 52. In this embodiment, a flexible tab 40 is attached to and extends along both bottom surface Y edge portions 24, 30. Disposed on both tab first surface side portions 46 is an adhesive which allows the tab first surface side portion 46 to be attached to a PV module 12 and the surface structure 52. In this embodiment, the plurality of flexible tabs 40 are folded under themselves so that the side portions 46 overlap. A space 54 is provided between the surface structure 52 and the bottom surface 16 of the PV modules 12.

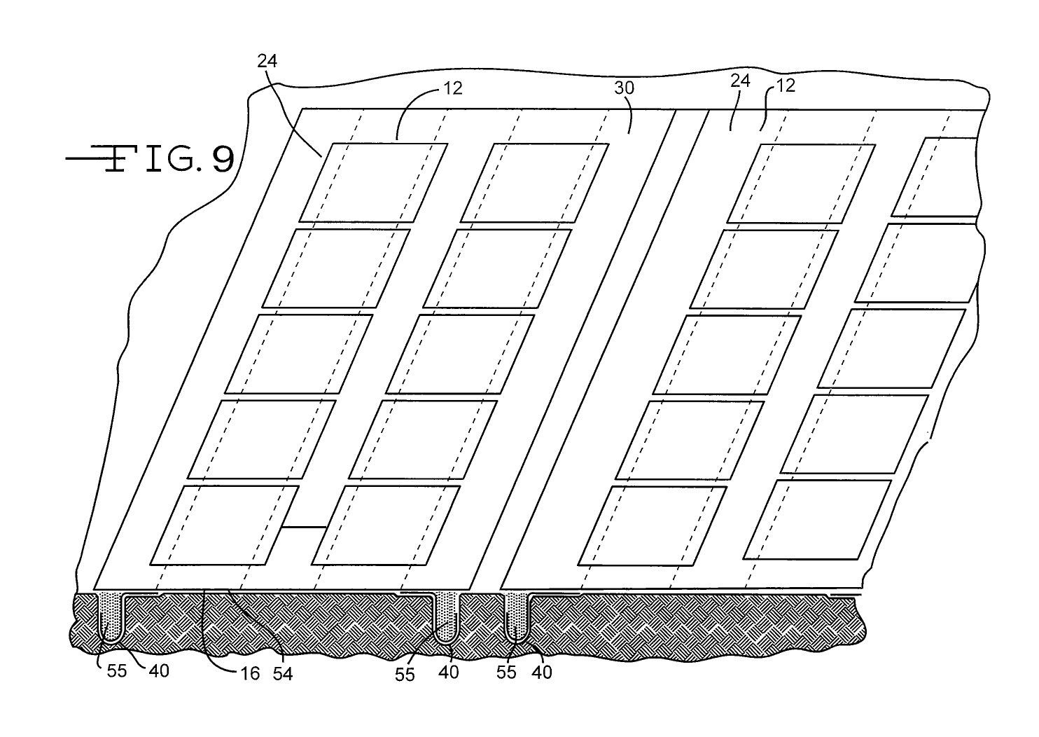

FIG. 8 depicts yet another embodiment of the present invention. As shown, a plurality of flexible tabs 40 are attached to the PV module bottom surface 16 and to the surface structure 52. In this embodiment, a plurality of flexible tabs 40 may be attached together to form pairs 56 of flexible tabs 40.

The plurality of flexible tabs 40 are attached together with an adhesive to form the flexible tab pairs 56. Each flexible tab pair 56 comprises a first flexible tab 58 and a second flexible tab 60. In an embodiment, the first flexible tab 58 and the second flexible tab 60 have the same composition. In another embodiment, the first flexible tab 58 and the second flexible tab 60 have a different composition. Regardless, it is preferred that the second flexible tab 60 has the same composition as the surface structure 52.

The first flexible tab 58 is attached to the second flexible tab 60 and a PV module 12. A first flexible tab first surface side portion 46 is attached to a bottom surface Y edge portion 24, 30 of a PV module 12. Only one of the first flexible tab second surface side portions 46 is attached to the second flexible tab 60. The second tab 60 is attached to the first flexible tab 58 and the surface structure 52. Only one of the second flexible tab first surface side portions 46 is attached to the first flexible tab 58. Additionally, only one of the second flexible tab second surface side portions 46 is attached to the surface structure 52. Preferably, the first flexible tabs 58 are attached to the PV module bottom surface 16 with an adhesive and the second flexible tabs 60 are attached to the surface structure 52 via welding. A space 54 is provided between the surface structure 52 and the bottom surface 16 of the photovoltaic module 12.

As shown in FIG. 9, in another embodiment, the PV module 12 has two flexible tabs 40 attached to its bottom surface 16. In this embodiment, the flexible tabs 40 are attached to and extend along both bottom surface Y edge portions 24, 30. A side portion 46 of each flexible tab 40 is attached to the bottom surface 16 of the PV module 12 and the center portion 48 and the opposite side portion 46 of the flexible tab 40 is left unattached. The center portion 48 and the side portion 46 which are not attached to the PV module 12 may be formed into a shape which retains ballast material 55 and fixedly positions the PV module 12 over the surface structure 52. For instance, a U-shape or a J-shape the may be formed with the unattached tab portions 46, 48. A space 54 is provided between the surface structure 52 and the bottom surface 16 of the photovoltaic modules 12.

It should be understood that various aspects of the embodiments shown in FIGS. 1-10 can be used separately or in combination.

As stated above, the PV structure 10 may comprise at least one PV module 12 and the plurality of flexible tabs 40 formed in a non-unitary manner. As such, the at least one PV module 12 can be mounted to, positioned over, and selectively removed from a surface structure 52 by severing a plurality of the flexible tabs 40. This provides for easy PV module removal without the module being torn and resulting in lower module resistance to moisture.

Thus, the present invention also provides a method for mounting a PV module 12. The method comprises providing a photovoltaic module 12. The photovoltaic module 12 is attached to a plurality of flexible tabs 40. The photovoltaic module 12 is positioned above a surface structure 52. The plurality of flexible tabs 40 are attached to the surface structure 52. A space 54 is created between the bottom surface 16 of the photovoltaic module 12 and the surface structure 52 after the plurality of flexible tabs 40 are attached to the surface structure 52. The method also comprises removing the photovoltaic module 12 from above the surface structure 52. Preferably, the photovoltaic module 12 is removed from above the surface structure 52 by severing the plurality of flexible tabs 40 attached to it. The method can also be utilized for selectively removing a plurality of PV modules 12. Severing the flexible tabs does not result in damage to the photovoltaic module.

In a further embodiment, the method for mounting a PV module 12 to a surface structure 52 also comprises providing a pair 56 of flexible tabs 40 attached to each PV module 12. Each pair 56 of flexible tabs 40 comprises a first flexible tab 58 and a second flexible tab 60. The first flexible tab 58 is attached to the second flexible tab 60 and a PV module 12. Preferably, each first flexible tab first surface side portion 46 is attached to a bottom surface Y edge portion 24, 30 of the PV module 12. The second flexible tab 60 is attached to the first flexible tab 58 and the surface structure 52. The method further comprises severing a plurality of flexible tabs 40, including the second flexible tab 60, attached to the PV module 12. As each second flexible tab 60 is severed, the PV module 12 is lifted away from the surface structure 58 to expose the next tab 40 to be severed. This step is repeated until the plurality of flexible tabs 40, or at least all the necessary flexible tabs 40, are severed. The PV modules 12 are then removed from the surface structure 52.

In accordance with the provisions of the patent statutes, the present invention has been disclosed in what are considered to represent its preferred embodiments. However, it should be noted that the invention can be practiced otherwise than as specifically illustrated and described without departing from its spirit or scope.

What is claimed is:

1. A photovoltaic structure, comprising:
a photovoltaic module having a top surface, a bottom surface, and a perimeter; and
a plurality of flexible tabs attached to the photovoltaic module, wherein the plurality of flexible tabs extend beyond the perimeter of the photovoltaic module.

2. The photovoltaic structure of claim 1, wherein the plurality of flexible tabs are attached to a bottom surface of the photovoltaic module by an adhesive and wherein the plurality of flexible tabs are attached to a surface structure.

3. The photovoltaic structure of claim 1, wherein the tabs are of a material which is different than the material of a bottom surface of the photovoltaic module.

4. The photovoltaic structure of claim 1, wherein the photovoltaic module is flexible and the plurality of flexible tabs and photovoltaic module are not unitary.

5. The photovoltaic structure of claim 1, wherein the flexible tabs are composed of a reinforced membrane material.

6. The photovoltaic structure of claim 1, further comprising a second photovoltaic module attached to at least one flexible tab of the plurality of flexible tabs.

7. The photovoltaic structure of claim 1, wherein the plurality of flexible tabs are selectively severed from a surface structure over which the photovoltaic module is deployed.

8. The photovoltaic structure of claim 1, wherein the plurality of flexible tabs includes two flexible tabs attached to Y edge portions of the photovoltaic module.

9. The photovoltaic structure of claim 1, wherein the plurality of flexible tabs are separated by a center portion of the photovoltaic module.

10. The photovoltaic structure of claim 1, wherein the plurality of flexible tabs extend beyond only two opposite edges of the PV module perimeter.

11. The photovoltaic structure of claim 2, wherein a space is provided between the bottom surface of the photovoltaic module and the surface structure.

12. The photovoltaic structure of claim 3, wherein the plurality of flexible tabs are attached to a surface structure and wherein the plurality of flexible tabs and the surface structure are composed of the same material.

13. The photovoltaic structure of claim 5, wherein the reinforced membrane material is comprised of one or more of HDPE, EPDM, TPO, Hypalon, or PIB.

14. The photovoltaic structure of claim 8, further comprising at least one flexible tab attached to each of the X edge portions of the photovoltaic module.

15. The photovoltaic structure of claim 8, wherein the two flexible tabs attached to the Y edge portions of the photovoltaic module extend the entire length of the edge portion to which they are attached.

16. A photovoltaic structure, comprising:
a photovoltaic module having a top surface, a bottom surface, and edge portions;
a plurality of flexible tabs attached to the photovoltaic module, wherein at least two flexible tabs are attached to bottom surface edge portions of the photovoltaic module; and
a surface structure attached to the plurality of flexible tabs so that a space is provided between the surface structure and the bottom surface of the photovoltaic module.

17. A method for mounting a photovoltaic module, comprising:
providing a photovoltaic module, wherein the photovoltaic module is attached to a plurality of flexible tabs and positioned above a surface structure, and the plurality of flexible tabs are attached to the surface structure; and
removing the photovoltaic module from above the surface structure.

18. The method for mounting a photovoltaic module of claim 17, further comprising forming a non-unitary photovoltaic structure by attaching the photovoltaic module to the plurality of flexible tabs with an adhesive.

19. The method for mounting a photovoltaic module of claim 17, further comprising severing the flexible tabs, wherein severing the flexible tabs does not result in damage to the photovoltaic module.

20. The method for mounting a photovoltaic module of claim 18, further comprising providing a space between a bottom surface of the photovoltaic module and the surface structure upon attaching the plurality of flexible tabs to the surface structure.
